(19) United States
(12) Patent Application Publication
(10) Pub. No.: US 2026/0009852 A1
(43) Pub. Date: Jan. 8, 2026

(54) TEST MODE CONTROL SYSTEM AND SYSTEM-ON-CHIP INCLUDING THE SAME

(71) Applicant: ITDA SEMICONDUCTOR CO., LTD., Hwaseong-si (KR)

(72) Inventors: Ahchan KIM, Hwaseong-si (KR); Hoyeon JEON, Seongnam-si (KR); Ingyu KIM, Hwaseong-si (KR); Jaesung LEE, Seoul (KR)

(73) Assignee: ITDA SEMICONDUCTOR CO., LTD., Hwaseong-si (KR)

(21) Appl. No.: 19/255,451

(22) Filed: Jun. 30, 2025

(30) Foreign Application Priority Data
Jul. 2, 2024 (KR) 10-2024-0086592
Aug. 16, 2024 (KR) 10-2024-0109522

(51) Int. Cl. G01R 31/3187; G01R 31/317; G01R 31/3185

(52) U.S. Cl. CPC G01R 31/3187; G01R 31/31725; G01R 31/318555; G01R 31/318572

(57) ABSTRACT

The present disclosure relates to a test mode control system capable of testing a clock component that configures a clock management unit and generating a test clock by driving the clock component that generates a functional clock and a system-on-chip including the same. The test mode control system according to an embodiment of the present disclosure includes: a test mode controller that transmits a clock control signal to a clock source that configures a high-speed domain of a clock management unit in a test mode; and a test multiplexer that transfers a clock control signal input from the test mode controller to the clock source in the test mode and transfers a clock control signal input from a clock control circuit corresponding to the clock source to the clock source in a functional mode.

### STATEMENT REGARDING GOVERNMENT SPONSORED RESEARCH OR DEVELOPMENT

This invention was made with support from the Ministry of SMEs and Startups through a grant funded by the Korea Technology and Information Promotion Agency for SMEs (TIPA), under Project Unique Number 1425182152 and Project Number RS-2023-00302523, within the Startup Growth Technology Development (R&D) program. The project titled “Low-Code Based Low-Power Semiconductor Solution” was executed by ITDA Semiconductor Co., Ltd., with the research period spanning from Jul. 1, 2023, to Jun. 30, 2026. However, no rights in the invention are held by the government of the Republic of Korea.

### CROSS-REFERENCE TO RELATED APPLICATION

This application claims the benefit of and priority to Korean Patent Application Nos. 10-2024-0086592, filed on Jul. 2, 2024, and 10-2024-0109522, filed on Aug. 16, 2024, the entire disclosures of which are incorporated herein by reference in their entirety.

### TECHNICAL FIELD

The present disclosure relates to a test mode control system and a system-on-chip including the same, and more particularly, to a test mode control system capable of testing clock components configuring a clock management unit and generating a test clock by driving the clock components that generate a functional clock, and to a system-on-chip including the same.

### BACKGROUND

A system-on-chip (SoC) refers to a technology that integrates various functional blocks such as a central processing unit (CPU), a memory, an interface, a digital signal processing circuit, and an analog signal processing circuit into a single semiconductor integrated circuit to implement a computer system or other electronic system, or an integrated circuit (IC) integrated according to the technology. The SoC has evolved into more complex systems including various functional blocks such as processors, multimedia, graphics, interfaces, and security.

The SoC may be driven in a test mode to detect defects during the design and manufacturing process and to verify that the SoC operates properly, and may be driven in a functional mode when passing a test and operating normally.

FIG. 1 is a block diagram illustrating a typical system-on-chip (SoC) device.

The SoC device may include an input/output pad 110, a clock management unit (CMU) 120, a power management unit (PMU) 130, and one or more intellectual property (IP) blocks 140, 150, 160. When the SoC device operates in a functional mode, the CMU 120 may generate a functional clock to be provided to each of the first to third IP blocks 140, 150, 160. For example, the CMU 120 may generate the first to third functional clocks (CLK1, CLK2, CLK3).

Each of the first to third IP blocks 140, 150, and 160 is connected to a system bus and may communicate with other IP blocks through the system bus. Each of the first to third IP blocks 140, 150, and 160 may include a processor, a graphic processor, a memory controller, and an input and output interface block . . . .

The CMU 120 may provide a first functional clock (CLK1) to the first IP block 140 when the first IP block 140 operates, provide a second functional clock (CLK2) to the second IP block 150 when the second IP block 150 operates, and provide a third functional clock (CLK3) to the third IP block 160 when the third IP block 160 operates. The PMU 130 controls power supplied to the SoC device. For example, when the SoC device enters a standby mode, the PMU 130 cuts off the power supply provided to the SoC device.

FIG. 2 is a detailed configuration block diagram illustrating a clock management unit 200 included in the SoC device of FIG. 1. The clock management unit 200 of FIG. 2 may be executed in a functional mode in which the SoC device operates normally. The clock management unit 200 may be the CMU 120 of FIG. 1.

Referring to FIG. 2, the clock management unit 200 includes a plurality of clock components 202, 204, 206, 208, 210, 212, 214 and a clock management unit controller (CMU controller) 216. The plurality of clock components 202, 204, 206, 208, 210, 212, 214 may generate a functional clock to be provided to an IP block. The frequencies of the functional clocks provided to each IP block may differ from one another. The CMU controller 216 controls the clock components 202, 204, 206, 208, 210, 212, 214 to provide a functional clock having a frequency required by each IP block.

The clock components may include a phase locked loop (PLL) controller 202, 204, a clock divider 206, 210, a clock multiplexer 208, and a clock gate 212, 214. Each clock component may include a clock source that processes a clock, and a clock control circuit that controls the clock source (CS). The CS may include, for example, a multiplexing circuit, a divider circuit, and a gate circuit.

The PLL controller 202 and 204 does not include an internal clock source, and may control a PLL disposed outside the clock management unit 200.

The clock dividers 206, 210 each include a divider circuit as the CS, and the clock control circuit (CC) of the clock dividers 206, 210 each controls the divider circuit. The divider circuit divides an input clock and outputs the divided clock, and the clock control circuit (CC) may control the division ratio of the divider circuit.

The clock multiplexer 208 includes a multiplexing circuit as the CS, and the clock control circuit (CC) of the clock multiplexer 208 controls the multiplexing circuit. The multiplexing circuit selectively outputs one of a plurality of input clocks. The clock control circuit (CC) may control which input clock the multiplexing circuit selects and outputs.

The clock gates 212 and 214 respectively include a gate circuit as a clock source (CS), and the clock control circuits (CC) of the clock gates 212 and 214 respectively control the gate circuits. The gate circuit activates the clock only when the operation of the IP block is required, so that the functional clock is provided to the IP block, and otherwise blocks the clock to control unnecessary clocks. The clock control circuit (CC) may control the gate circuit to stop or activate the functional clock.

The CMU controller 216 includes a register, and information necessary for controlling and setting the operation of the clock management unit 200 is recorded in the register as a register transfer level (RTL) code. The register of the CMU controller 216 is written with the RTL code that describes the operation of the clock control circuit of each clock component, and this RTL code may be implemented as actual clock management unit hardware using a hardware design tool.

The clock management unit of FIG. 2 is executed in a functional mode in which the SoC device operates normally, and provides a functional clock to the IP block.

In the manufacturing process of the SoC, it is necessary to test whether the IP block operates normally, and to provide a test clock to the IP block in the test mode.

FIG. 3 is a block diagram illustrating a conventional test clock generation system.

The conventional test clock generation system includes a test clock generation unit 310 that outputs a test clock, and a test multiplexer (Test MUX) 320, 330 that selectively provides the IP block with a functional clock provided from the clock management unit 200 and a test clock provided from the test clock generation unit 310.

The test clock generation unit 310 generates a test clock separate from the functional clock. The test clock may be branched from any one clock component of the clock management unit 200. For example, a clock generated from any one PLL may be provided to the test multiplexer through a path different from a functional clock generation path.

The test multiplexer 320, 330 provides the test clock input from the test clock generation unit 310 to the IP block in the test mode, and provides the functional clock input from the clock management unit 200 to the IP block in the functional mode.

Such a conventional test clock generation system does not drive the clock component of the clock management unit in the test mode of the SoC device, and thus may not test whether the clock component operates normally.

In addition, since the functional clock generation path and the test clock generation path are different, the frequency of the test clock provided to the IP block in the test mode and the frequency of the functional clock provided to the IP block in the functional mode may be different, which may cause a difference between the voltage margin in the test mode and the voltage margin in the functional mode. Due to this difference in voltage margin, there is an issue in that the defect rate increases and the chip yield decreases during mass production.

### SUMMARY

An aspect of the present disclosure is directed to providing a test mode control system capable of generating a test clock through the same path as a functional clock generation path in a test mode and providing the same to an IP block and testing a clock management unit and a system-on-chip including the same.

The test mode control system according to an embodiment of the present disclosure includes a test mode controller that transmits a clock control signal to a clock source that configures a high-speed domain of a clock management unit in a test mode, and a test multiplexer that transfers a clock control signal input from the test mode controller to the clock source in the test mode and transfers a clock control signal input from a clock control circuit corresponding to the clock source to the clock source in a functional mode.

Preferably, the clock source and the test multiplexer are matched one-to-one.

Preferably, the test mode control system further includes a scan controller that controls a reference clock supplied to a clock control circuit that configures a low-speed domain of the clock management unit in the test mode.

Preferably, the test mode controller is a controller based on a built-in IEEE1687 standard.

Preferably, the test mode controller includes a test mode test data register (TDR) that activates or deactivates the test multiplexer to be in the test mode, and a test control test data register (TDR) that enables a clock control signal to be transmitted to the test multiplexer.

More preferably, the test mode TDR and the test control TDR are set via an internal joint test action group (IJTAG) interface.

More preferably, the test control TDR includes a flip-flop chain of the number of bits of the clock control signal.

Preferably, the test mode control system further includes an IP block test controller that provides a test clock generated in the high-speed domain of the clock management unit in the test mode to an IP block.

A system-on-chip according to an embodiment of the present disclosure includes a clock management unit that includes at least one clock component, and a test mode control system that tests the clock component in a test mode and generates a test clock through the clock component. The test mode control system includes a test mode controller that transmits a clock control signal to a clock source that configures a high-speed domain of the clock management unit in the test mode, and a test multiplexer that transfers a clock control signal input from the test mode controller to the clock source in the test mode and transfers a clock control signal input from a clock control circuit corresponding to the clock source to the clock source in a functional mode.

Preferably, the clock source and the test multiplexer are matched one-to-one.

Preferably, the test mode control system further includes a scan controller that controls a reference clock supplied to a clock control circuit that configures a low-speed domain of the clock management unit in the test mode.

Preferably, the test mode controller is a controller based on a built-in IEEE1687 standard.

Preferably, the test mode controller includes a test mode test data register (TDR) that activates or deactivates the test multiplexer to be in the test mode, and a test control test data register (TDR) that enables a clock control signal to be transmitted to the test multiplexer.

More preferably, the test mode TDR and the test control TDR are set via an internal joint test action group (IJTAG) interface.

More preferably, the test control TDR includes a flip-flop chain of the number of bits of the clock control signal.

Preferably, the test mode control system further includes an IP block test controller that provides a test clock generated in the high-speed domain of the clock management unit in the test mode to an IP block.

### Advantageous Effects

An embodiment of the present disclosure provides the following benefits.

An embodiment of the present disclosure is configured to generate a test clock through the same path as a functional clock generation path, thereby enabling testing of whether the clock components configuring the functional clock generation path operate normally in a test mode, and thus expanding the test coverage.

An embodiment of the present disclosure is configured to separate the clock components into a low-speed domain and a high-speed domain, wherein the low-speed domain is tested using a reference clock of a scan chain for logic testing of a system-on-chip device, and the high-speed domain is tested using the same circuit as the functional clock generation path to generate a test clock having the same frequency as the functional clock.

An embodiment of the present disclosure is configured to provide the test clock to an IP block when the system-on-chip device is driven in the test mode, thereby so that the IP block test is smoothly performed.

Since an embodiment of the present disclosure is configured to generate the test clock through the same path as the functional clock generation path, the frequency of the test clock is the same as the frequency of the functional clock used in a functional mode, so that the voltage margin in the test mode and the voltage margin in the functional mode are identical, thereby reducing the defect rate in mass production and improving the chip yield.

The benefits of the present disclosure are not limited to those mentioned above, and other benefits not mentioned herein will be clearly understood by those having ordinary skill in the technical field to which the present disclosure pertains (hereinafter, “those skilled in the art”) from the following description.

### BRIEF DESCRIPTION OF THE DRAWINGS

Embodiments of the present disclosure will be described with reference to the accompanying drawings described below, where similar reference numerals indicate similar elements, but embodiments are not limited thereto, in which:

FIG. 1 is a block diagram illustrating a typical system-on-chip (SoC) device;

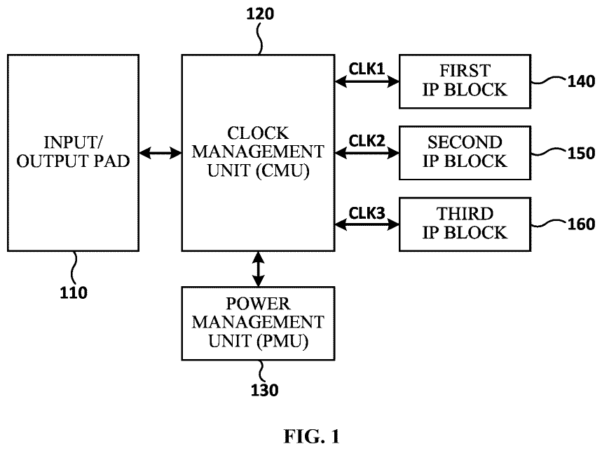

FIG. 2 is a detailed configuration block diagram illustrating a clock management unit included in the SoC device of FIG. 1;

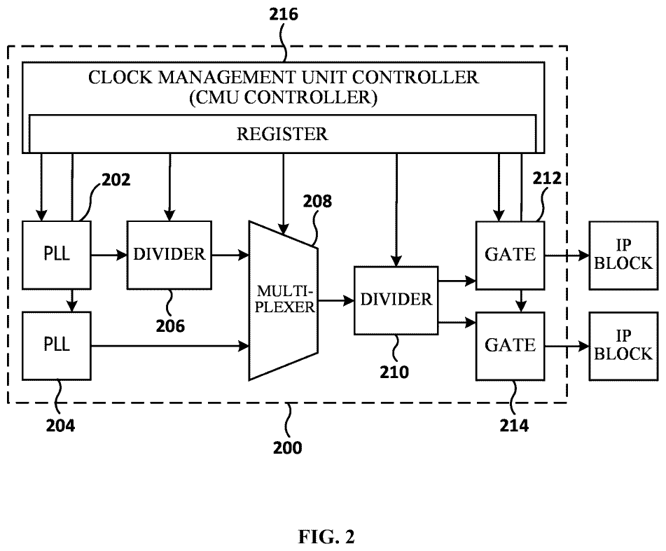

FIG. 3 is a block diagram illustrating a conventional test clock generation system;

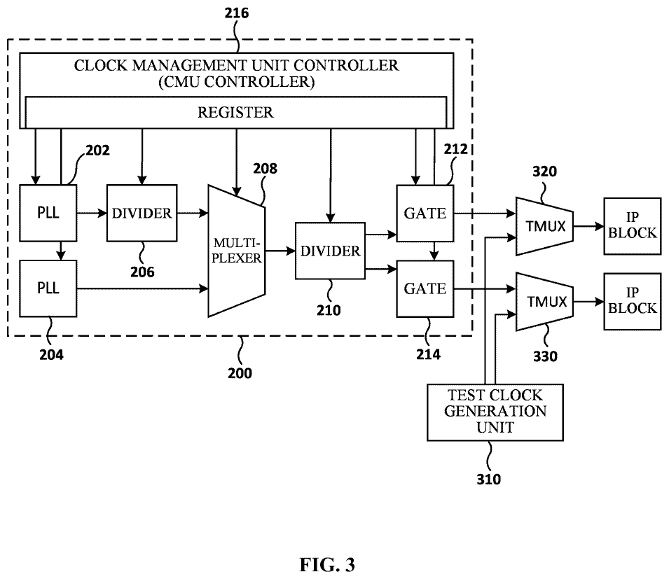

FIG. 4 is a partial detailed diagram illustrating a clock management unit to which an embodiment of the present disclosure is applied; and

FIG. 5 is a block diagram illustrating a test mode control system according to an embodiment of the present disclosure.

### DETAILED DESCRIPTION

Hereinafter, specific details for the practice of the present disclosure will be described in detail with reference to the accompanying drawings. However, in the following description, detailed descriptions of well-known functions or configurations will be omitted when it may make the subject matter of the present disclosure rather unclear.

In the accompanying drawings, the same or corresponding components are assigned the same reference numerals. Further, in the following description of the embodiments, duplicate descriptions of the same or corresponding components may be omitted. However, even if descriptions of components are omitted, it is not intended that such components are not included in any embodiment.

The advantages and features of the embodiments of the present disclosure and methods of achieving the same will be apparent from the embodiments described below in connection with the accompanying drawings. However, the present disclosure is not limited to the disclosed embodiments disclosed below, and may be implemented in various different forms, and the present embodiments are merely provided to fully disclose the scope of embodiments to those skilled in the art to which the present disclosure pertains.

Unless otherwise defined, all terms (including technical and scientific terms) used herein have the same meaning as commonly understood by those skilled in the technical field to which the present disclosure pertains. It will be further understood that terms, such as those defined in commonly used dictionaries, should not be interpreted in an idealized or overly formal sense unless expressly so defined herein.

For example, the term “technique” may refer to a system, method, computer readable instruction, module, algorithm, hardware logic, and/or operation as permitted by the context described above and throughout a document.

As used herein, the singular forms are intended to include the plural forms as well, unless the context clearly indicates the singular forms. Further, the plural forms are intended to include the singular forms as well, unless the context clearly indicates the plural forms. Further, throughout the description, when a portion is stated as including a component, it is to be understood that the portion may additionally include other components, unless explicitly stated otherwise.

In this present disclosure, the terms “comprising,” “having,” or the like are used to specify that features, steps, operations, elements and/or components exist, and they do not preclude the addition of one or more other features, steps, operations, elements, components, and/or combinations thereof.

In the present disclosure, when a particular component is referred to as being “coupled to,” “combined with,” “connected to,” “related to,” or as “responding to” any other component, the particular component may be directly coupled to, combined with, connected to, and/or related to, or may directly respond to the other component; however, the present disclosure is not limited to the relationship. For example, there may be one or more intermediate components between a particular component and another component. In addition, in the present disclosure, “and/or” may include one or more of the listed items or a combination of at least a portion of one or more of the listed items.

In the present disclosure, the terms such as “first” and “second” are used to distinguish a particular component from the other components, and thus the component should not be limited by those terms. For example, a “first” component may be used to indicate a component in a form similar to or the same as a “second” component.

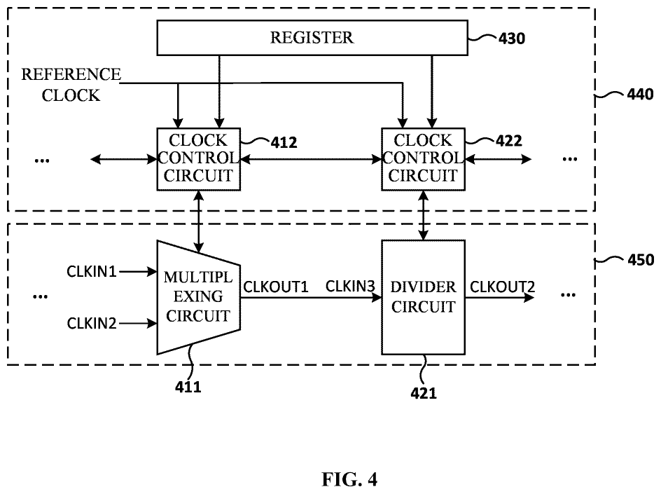

FIG. 4 is a partial detailed diagram illustrating a clock management unit to which an embodiment of the present disclosure is applied.

The clock management unit to which an embodiment of the present disclosure is applied may include a plurality of clock components. The clock components may include a PLL controller, a clock multiplexer, a clock divider, and a clock gate. FIG. 4 illustrates an example in which a clock multiplexer and a clock divider are connected. Any clock components may be additionally connected to a front end of the clock multiplexer and a rear end of the clock divider.

The clock component may include a clock source that processes a clock and a clock control circuit that controls each clock source, and the clock source may include a multiplexing circuit, a divider circuit, and a gate circuit.

For example, the clock multiplexer may include a multiplexing circuit 411 that processes a clock and a clock control circuit 412 that controls the multiplexing circuit 411, and the clock divider may include a divider circuit 421 that processes a clock and a clock control circuit 422 that controls the divider circuit 421.

The multiplexing circuit 411 receives two or more input clocks (CLKIN1, CLKIN2) from two or more clock components at a front end thereof, receives a multiplexer selection signal from the clock control circuit 412, selects one clock among the two or more input clocks (CLKIN1, CLKIN2) as an output clock (CLKOUT1), and provides the same as a clock component at a rear end thereof. The clock control circuit 412 receives multiplexer selection information from a register 430 and outputs the multiplexer selection signal to the multiplexing circuit 411.

The divider circuit 421 receives the output clock of the clock component at a front end thereof as an input clock (CLKIN3), receives a clock division ratio from the clock control circuit 422, and provides an output clock (CLKOUT2) obtained by dividing the input clock (CLKIN3) by the division ratio as a clock component at a rear end thereof. The clock control circuit 422 receives division ratio information from the register 430 and provides the same to the divider circuit 421.

The multiplexing circuit 411 and the divider circuit 421 may be collectively referred to as clock sources 411, 421.

The clock control circuits 412, 422 of the clock components are usually driven by receiving a reference clock of about several tens of MHz. The clock sources 411, 421 of the clock components process a high-speed clock of several hundreds of MHz to several GHz.

The clock components of the clock management unit may be separated into a low-speed domain 440 configured of the clock control circuits 412, 422 and a high-speed domain 450 configured of the clock sources 411, 421.

When the components of the low-speed domain 440 and the high-speed domain 450 of the clock management unit are tested, since the operating clock frequency of the low-speed domain 440 and the operating clock frequency of the high-speed domain 450 are different, the test of the low-speed domain 440 and the test of the high-speed domain 450 are tested separately, and different test methods are respectively applied.

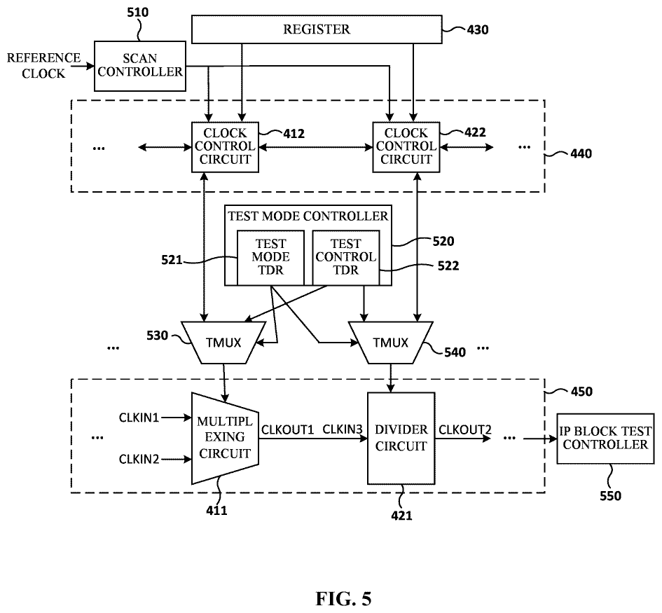

FIG. 5 is a block diagram illustrating a test mode control system according to an embodiment of the present disclosure.

The test mode control system of an embodiment of the present disclosure tests whether the clock components configuring the clock management unit are operating normally in a test mode, and generates a test clock along a functional clock generation path of the clock management unit so as to be provided to the IP block.

The test mode control system of an embodiment of the present disclosure is configured to include a scan controller 510 that controls a reference clock supplied to the clock control circuit 412, 422 configuring the low-speed domain 440 of the clock management unit in a test mode, a test mode controller 520 that transmits a clock control signal to the clock source 411, 421 configuring the high-speed domain 450 of the clock management unit in the test mode, and a test multiplexer (Test MUX) 530, 540 that transmits a clock control signal input from the test mode controller 520 to the clock source 411, 421 in the test mode.

The test multiplexers 530, 540 transmit a clock control signal input from the clock control circuit 412, 422 to the clock source 411, 421 in a functional mode. The test multiplexers 530, 540 may be configured to be matched one-to-one with the clock sources 411, 421. For example, the first test multiplexer 530 may be matched to the multiplexing circuit 411, and the second test multiplexer 540 may be matched to the divider circuit 421.

When a system-on-chip operates in a test mode, the first test multiplexer 530 transmits a clock control signal input from the test mode controller 520 to the multiplexing circuit 411, and the second test multiplexer 540 transmits a clock control signal input from the test mode controller 520 to the divider circuit 421. When the system-on-chip operates in a functional mode, the first test multiplexer 530 transmits the clock control signal input from the clock control circuit 412 to the multiplexing circuit 411, and the second test multiplexer 540 transmits the clock control signal input from the clock control circuit 422 to the divider circuit 421. Although not illustrated, test multiplexers may also be configured to match a clock source at a front end of the multiplexing circuit and a clock source at a rear end of the divider circuit, respectively.

The test mode controller 520 may include a test mode test data register (TDR) 521 that activates or deactivates the test multiplexers 530, 540 in the test mode, and a test control test data register (TDR) 522 that provides a clock control signal to the test multiplexers 530, 540 activated in the test mode. The test multiplexers 530, 540 operate in a functional mode when the test mode is deactivated and transmit the clock control signal input from the clock control circuit 412, 422 to the clock sources 411, 421. The test multiplexers 530, 540 operate in a test mode when the test mode is activated and transmit the clock control signal input from the test control TDR 522 of the test mode controller 520 to the clock sources 411, 421.

The test mode controller 520 may be a controller based on a built-in IEEE1687 standard. The test mode controller 520 may configure the test mode TDR 521 and the test control TDR 522 via an internal joint test action group (IJTAG) interface.

The test mode TDR 521 may be configured with one flip-flop, and the output data of the test mode TDR 521 may be transmitted to the test multiplexers 530, 540 to activate/deactivate the test mode, and the test multiplexers 530, 540 may operate in the test mode/functional mode.

The test control TDR 522 may be configured with a flip-flop chain as many as the number of bits of the clock control signal provided to the clock source. For example, when the number of input clocks of the multiplexing circuit is 2, the multiplexing circuit may output a 1-bit clock control signal, and may output a 4-bit clock control signal depending on the division ratio of the divider circuit. In this connection, the test control TDR may be configured with one flip-flop for outputting the clock control signal to the multiplexing circuit and four flip-flops for outputting the clock control signal to the divider circuit in the form of a shift register chain.

The test mode control system may further include an IP block test controller 550 between the clock management unit and the IP block. The IP block test controller 550 may control the test clock generated by the clock management unit in the test mode to be transmitted to the IP block. In addition, the frequency of the test clock may be detected to determine whether the clock components of the clock management unit operate normally.

Hereinafter, the operation of the test mode control system according to an embodiment of the present disclosure will be described.

In the test mode of a system-on-chip device, the scan controller 510 controls the reference clock and provides the same to the clock control circuit 412, 422 of the low-speed domain 440. Since the scan controller 510 tests the clock control circuit 412, 422 using the reference clock of a scan chain for a logic test in the test mode, the components of the low-speed domain 440 may be tested by being linked to the scan chain for the logic test.

In the test mode of the system-on-chip device, the test mode controller 520 activates the test multiplexers 530, 540 to be in the test mode through the test mode TDR 521. Then, the test multiplexers 530, 540 are in a state of providing the clock control signal provided from the test mode controller 520 to the clock sources 411, 421. In this connection, the test mode controller 520 provides the clock control signal to the clock sources 411, 421 through the test control TDR 522, so that the test clock is generated through the clock sources 411, 421. The test clock may be provided to the IP block through the IP block test controller 550 and may be used for the IP block test.

In the functional mode of the system-on-chip device, the test mode controller 520 deactivates the test mode of the test multiplexers 530, 540 through the test mode TDR 521. Then, the test multiplexers 530, 540 are in a state of providing the clock control signal provided from the clock control circuit 412, 422 to the clock sources 411, 421. The clock control circuits 412, 422 provide each clock control signal to the clock sources 411, 421 based on the information transmitted from each register 430, and the functional clock is generated through the clock sources 411, 421.

As such, since the test clock generation path in the test mode and the functional clock generation path in the functional mode are the same, the test clock of the same frequency as the functional clock may be provided to the IP block.

In addition, in the test mode, the low-speed domain of the clock management unit may be tested by being linked to a scan chain for the logic test, and the high-speed domain of the clock management unit may be tested by providing clock control signals to clock sources through the test mode controller to determine whether a test clock of a desired frequency is generated.

It should be understood that many variations and modifications may be made to the above-described embodiments, and the element thereof is one of other permissible examples. All the modifications and variations are intended to be included in the scope of the present disclosure and protected by the following claims. The exemplary embodiment of the present disclosure described above may be implemented in the form of a program command which may be executed through various computer components to be recorded in a computer readable recording medium. The computer readable recording medium may include solely a program command, a data file, and a data structure or a combination thereof. The program commands recorded in the computer readable recording medium may be specifically designed or constructed for the present disclosure or known to those skilled in the art of a computer software to be used. Examples of the computer readable recording medium include magnetic media such as a hard disk, a floppy disk, or a magnetic tape, optical recording media such as a CD-ROM or a DVD, magneto-optical media such as a floptical disk, and a hardware device which is specifically configured to store and execute the program command such as a ROM, a RAM, and a flash memory. Examples of the program command include not only a machine language code which is generated by a compiler but also a high level language code which may be executed by a computer using an interpreter. The hardware device may operate as one or more software modules in order to perform the operation of the present disclosure and vice versa.

Although the present invention has been described above with specific matters such as specific components, limited embodiments, and drawings, this is merely provided to aid a more comprehensive understanding of the present invention, and the present invention is not limited to the above embodiments, and various modifications and alterations may be devised from such descriptions by those having ordinary skill in the art to which the present invention pertains.

The spirit of the present disclosure is defined by the appended claims rather than by the description preceding them, and all changes and modifications that fall within metes and bounds of the claims, or equivalents of such metes and bounds are therefore intended to be embraced by the range of the spirit of the present disclosure.

[Detailed Description of Main Elements]

| | |
|---|---|
| 411: multiplexing circuit | 412: clock control circuit |
| 421: divider circuit | 422: clock control circuit |
| 430: register | 440: low-speed domain |
| 450: high-speed domain | 510: scan controller |
| 520: test mode controller | 521: test mode TDR |
| 522: test control TDR | 530, 540: test multiplexer |
| 550: IP block test controller | |

What is claimed is:

1. A test mode control system comprising:
a test mode controller that transmits a clock control signal to a clock source that configures a high-speed domain of a clock management unit in a test mode; and
a test multiplexer that transfers a clock control signal input from the test mode controller to the clock source in the test mode and transfers a clock control signal input from a clock control circuit corresponding to the clock source to the clock source in a functional mode.

2. The test mode control system of claim 1, wherein the clock source and the test multiplexer are matched one-to-one.

3. The test mode control system of claim 1, further comprising a scan controller that controls a reference clock supplied to a clock control circuit that configures a low-speed domain of the clock management unit in the test mode.

4. The test mode control system of claim 1, wherein the test mode controller is a controller based on a built-in IEEE1687 standard.

5. The test mode control system of claim 1, wherein the test mode controller comprises a test mode test data register (TDR) that activates or deactivates the test multiplexer to be in the test mode, and a test control test data register (TDR) that enables a clock control signal to be transmitted to the test multiplexer.

6. The system of claim 5, wherein the test mode TDR and the test control TDR are set via an internal joint test action group (IJTAG) interface.

7. The test mode control system of claim 5, wherein the test control TDR comprises a flip-flop chain of the number of bits of the clock control signal.

8. The test mode control system of claim 1, further comprising an IP block test controller that provides a test clock generated in the high-speed domain of the clock management unit in the test mode to an IP block.

9. A system-on-chip comprising:
a clock management unit that comprises at least one clock component; and
a test mode control system that tests the clock component in a test mode and generates a test clock through the clock component,
wherein the test mode control system comprises:
a test mode controller that transmits a clock control signal to a clock source that configures a high-speed domain of the clock management unit in the test mode; and
a test multiplexer that transfers a clock control signal input from the test mode controller to the clock source in the test mode and transfers a clock control signal input from a clock control circuit corresponding to the clock source to the clock source in a functional mode.

10. The system-on-chip of claim 9, wherein the clock source and the test multiplexer are matched one-to-one.

11. The system-on-chip of claim 9, wherein the test mode control system further comprises a scan controller that controls a reference clock supplied to a clock control circuit that configures a low-speed domain of the clock management unit in the test mode.

12. The system-on-chip of claim 9, wherein the test mode controller is a controller based on a built-in IEEE1687 standard.

13. The system-on-chip of claim 9, wherein the test mode controller comprises a test mode test data register (TDR) that activates or deactivates the test multiplexer to be in the test mode, and a test control test data register (TDR) that enables a clock control signal to be transmitted to the test multiplexer.

14. The system-on-chip of claim 13, wherein the test mode TDR and the test control TDR are set via an internal joint test action group (IJTAG) interface.

15. The system-on-chip of claim 13, wherein the test control TDR comprises a flip-flop chain of the number of bits of the clock control signal.

16. The system-on-chip of claim 9, the test mode control system further comprises an IP block test controller that provides a test clock generated in the high-speed domain of the clock management unit in the test mode to an IP block.
